(19) United States
(12) Patent Application Publication
(10) Pub. No.: US 2026/0024726 A1
(43) Pub. Date: Jan. 22, 2026

(54) PLASMA PROCESSING APPARATUS AND PLASMA PROCESSING APPARATUS INNER MEMBER

(71) Applicant: Tokyo Electron Limited, Tokyo (JP)

(72) Inventors: Masaya HERAI, Miyagi (JP); Masanori ASAHARA, Miyagi (JP)

(73) Assignee: Tokyo Electron Limited, Tokyo (JP)

(21) Appl. No.: 19/340,964

(22) Filed: Sep. 26, 2025

Related U.S. Application Data
(63) Continuation of application No. PCT/JP2024/011631, filed on Mar. 25, 2024.

(30) Foreign Application Priority Data
Apr. 4, 2023 (JP) 2023-060816

(51) Int. Cl. H01J 37/32

(52) U.S. Cl. CPC H01J 37/3244; H01J 2237/2007

(57) ABSTRACT

A plasma processing apparatus includes a plasma processing apparatus inner member including a gas supply path and a forming portion in which the gas supply path is formed. The gas supply path has a representative length d₁ and a longest length d₂ in a cross-section perpendicular to a longitudinal direction of the gas supply path. The representative length d₁ is 0.5 mm or less, a ratio d₂/d₁ of the longest length d₂ to the representative length d₁ is 2 or more, an other end is not visible from one end in a plan view, and the forming portion has a thickness of 2 mm or more.

### CROSS-REFERENCE TO RELATED APPLICATIONS

This application is a bypass continuation application of international application No. PCT/JP2024/011631 filed Mar. 25, 2024, and which claims the benefit of priority from Japanese Patent Application No. 2023-060816, filed on Apr. 4, 2023. The entire contents of both of these applications are incorporated herein by reference.

### TECHNICAL FIELD

The present disclosure relates to a plasma processing apparatus and a plasma processing apparatus inner member.

### BACKGROUND

PTL 1 discloses a configuration in which a gas flow path having a bent portion is provided in an upper electrode of a plasma processing apparatus. PTL 2 discloses a configuration in which an upper electrode includes a through-hole for passing a gas, the through-hole being provided in a manner that branches via a recess. PTL 3 discloses a configuration in which a gas supply pipe having an embedment member is provided in a lower electrode of a plasma processing apparatus.

### CITATION LIST

### Patent Documents

PTL 1: JP2016-96342A

PTL 2: JP2023-2168A

PTL 3: JP2019-149422A

### SUMMARY

The technique according to the present disclosure prevents occurrence of abnormal discharge in a plasma processing apparatus.

According to an aspect of the present disclosure, a plasma processing apparatus includes a plasma processing apparatus inner member including a gas supply path and a forming portion in which the gas supply path is formed. The gas supply path has a representative length d₁ and a longest length d₂ in a cross-section perpendicular to a longitudinal direction of the gas supply path. The representative length d₁ is 0.5 mm or less, a ratio d₂/d₁ of the longest length d₂ to the representative length d₁ is 2 or more, an other end is not visible from one end in a plan view, and the forming portion has a thickness of 2 mm or more.

According to the present disclosure, it is possible to prevent the occurrence of abnormal discharge in the plasma processing apparatus.

### BRIEF DESCRIPTION OF DRAWINGS

FIG. 1 is a diagram illustrating a configuration example of a plasma processing system according to one embodiment.

FIG. 2 is a cross-sectional view illustrating the configuration example of the plasma processing apparatus according to one embodiment.

FIG. 3 is a partial cross-sectional view illustrating a configuration example of a gas supply path according to a first embodiment.

FIG. 4 is a partial cross-sectional view illustrating a configuration example of the gas supply path according to the first embodiment.

FIG. 5 is a partial plan view illustrating a configuration example of the gas supply path according to the first embodiment.

FIG. 6 is a partial plan view illustrating a configuration example of the gas supply path according to the first embodiment.

FIG. 7 is a partial plan view illustrating a configuration example of the gas supply path according to the first embodiment.

FIG. 8 is a diagram illustrating a configuration example of the gas supply path according to the first embodiment.

FIG. 9 is a diagram illustrating an operation example of the gas supply path according to the first embodiment.

FIG. 10 is a partial cross-sectional view illustrating a modification of the gas supply path according to the first embodiment.

FIG. 11 is a partial cross-sectional view illustrating a modification of the gas supply path according to the first embodiment.

FIG. 12 is a partial cross-sectional view illustrating a modification of the gas supply path according to the first embodiment.

FIG. 13 is a partial plan view illustrating a modification of the gas supply path according to the first embodiment.

FIG. 14 is a partial cross-sectional view illustrating a modification of the gas supply path according to the first embodiment.

FIG. 15 is a partial plan view illustrating a modification of the gas supply path according to the first embodiment.

FIG. 16 is a partial cross-sectional view illustrating a modification of the gas supply path according to the first embodiment.

FIG. 17 is a partial plan view illustrating a modification of the gas supply path according to the first embodiment.

FIG. 18 is a partial cross-sectional view illustrating a modification of the gas supply path according to the first embodiment.

FIG. 19 is a partial cross-sectional view illustrating a configuration example of a gas supply path according to a second embodiment.

FIG. 20 is a diagram illustrating an operation example of the gas supply path according to the second embodiment.

FIG. 21 is a partial cross-sectional view illustrating a modification of the gas supply path according to the second embodiment.

FIG. 22 is a partial cross-sectional view illustrating a modification of the gas supply path according to the second embodiment.

FIG. 23 is a partial cross-sectional view illustrating a modification of the gas supply path according to the second embodiment.

### DETAILED DESCRIPTION

In a process of manufacturing a semiconductor device, a processing module containing a semiconductor wafer (hereinafter referred to as a “substrate”) is placed under reduced pressure, and various processing steps including plasma processing are performed on the substrate. The plasma processing is performed using, for example, a plasma processing apparatus in which a plurality of processing modules are disposed around a common transfer module.

In a plasma processing chamber in the processing module, various members related to plasma generation, substrate support, and the like are provided. It is understood that a gas supply path formed in these members includes a portion where abnormal discharge may occur.

In PTLs 1 and 2, in an upper electrode which is a member in which abnormal discharge may occur, a gas supply path for supplying a process gas has a labyrinth structure that includes a bend, a branch, or the like, which prevents positive ions from entering from a plasma processing space and prevents occurrence of the abnormal discharge. In PTL 3, in an electrostatic chuck which is a member in which abnormal discharge may occur, by providing the embedment member in a heat transfer gas supply path for supplying a heat transfer gas, it is possible to shorten a straight travelling distance of electrons.

In the related art, a method of forming a gas supply path as disclosed in the above-described documents by performing processing such as machining center processing (MC processing), water jet processing, or electrical discharge machining on a silicon member may be used. The MC processing or water jet processing cannot process holes with a high aspect ratio above a certain level, and tends to result in a tapered shape. In the electrical discharge machining, a machining time is extremely long, and only a material having extremely low resistance such as silicon can be processed. Therefore, in the above-described processing method, it is necessary to have a complicated configuration such as a labyrinth structure as disclosed in the above-described document or a configuration that includes other members such as an embedment member. The water jet processing simply involves spraying high-pressure water onto an object, and is different from water laser processing, which will be described later.

Therefore, the technique according to the present disclosure prevents occurrence of abnormal discharge in the plasma processing apparatus inner member. Specifically, a gas supply path formed in the member capable of preventing the occurrence of abnormal discharge in the plasma processing apparatus inner member is provided.

Hereinafter, a configuration of a substrate processing apparatus according to the present embodiment will be described with reference to the drawings. The same reference numerals will be given to elements having substantially the same functional configurations throughout the specification, and redundant description thereof will be omitted.

### <Plasma Processing System>

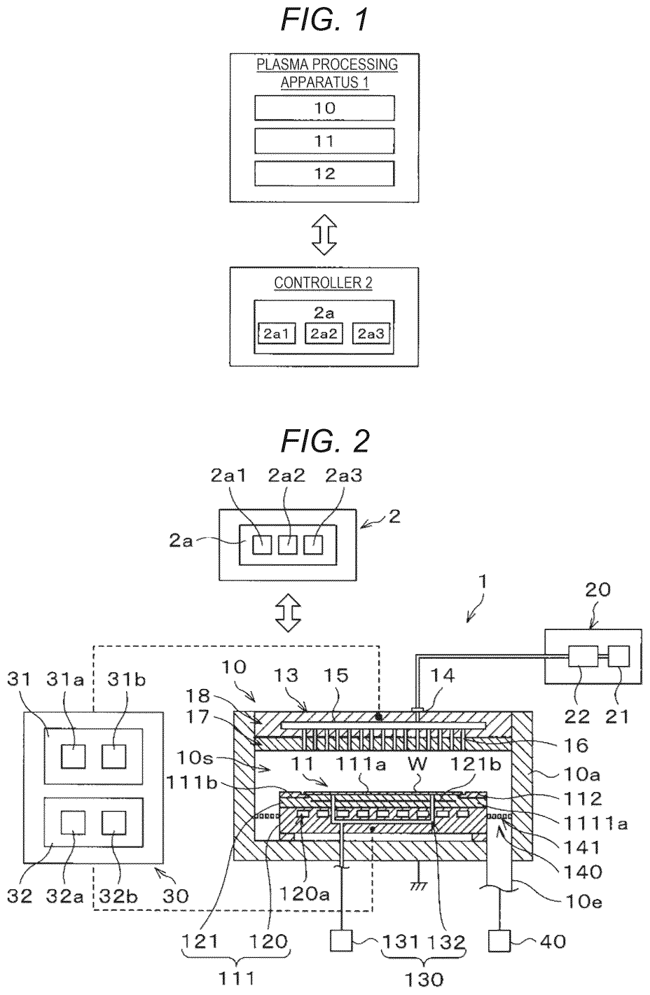

FIG. 1 is a diagram for explaining an example of a configuration of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include circuitry such as a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2a1 may be a central processing unit (CPU) and may be implemented on circuitry such as a field programmable gate array (FPGA), application specific integrated circuit (ASIC), or the like. The storage 2a2 may include circuitry such as a random access memory (RAM), a read only memory (ROM), a hard disk drive (HDD), a solid state drive (SSD), or a combination thereof. The communication interface 2a3 may include circuitry to communicate with the plasma processing apparatus 1 via a communication line such as a local area network (LAN).

### <Plasma Processing Apparatus>

Hereinafter, a configuration example of a capacitively-coupled plasma processing apparatus as an example of the plasma processing apparatus 1 will be described. FIG. 2 is a view for explaining an example of a configuration of a capacitively-coupled plasma processing apparatus.

The capacitively-coupled plasma processing apparatus 1 includes the plasma processing chamber 10, the gas supply 20, a power source 30, and the exhaust system 40. The plasma processing apparatus 1 further includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 120 and an electrostatic chuck 121. The base 120 includes a conductive member. The conductive member of the base 120 may function as a lower electrode. The electrostatic chuck 121 is disposed on the base 120. The electrostatic chuck 121 includes a ceramic member 121a and an electrostatic electrode 121b disposed in the ceramic member 121a. The ceramic member 121a has the central region 111a. In one embodiment, the ceramic member 121a also has the annular region 111b. Other members that surround the electrostatic chuck 121, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 121 and the annular insulating member. At least one RF/DC electrode coupled to an RF power source 31 and/or a DC power source 32, which will be described later, may be disposed in the ceramic member 121a. In this case, at least one RF/DC electrode functions as the lower electrode. When a bias RF signal and/or DC signal, which will be described later, is supplied to at least one RF/DC electrode, the RF/DC electrode is also referred to as a bias electrode. The conductive member of the base 120 and the at least one RF/DC electrode may function as a plurality of lower electrodes. The electrostatic electrode 121b may also function as the lower electrode. The substrate support 11 therefore includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

The substrate support 11 includes a heat transfer gas supply 130 configured to supply a heat transfer gas to a gap between a rear surface of the substrate W and the central region 111a or a gap between a rear surface of the ring assembly 112 and the annular region 111b. The heat transfer gas supply 130 includes at least one heat transfer gas source 131 and a heat transfer gas introduction port 132. Details of the heat transfer gas supply 130 will be described later.

The substrate support 11 may include a temperature control module configured to adjust at least one of the electrostatic chuck 121, the ring assembly 112, and the substrate W to a target temperature. The temperature control module may include a heater, a heat transfer medium, a flow path 120a, or a combination thereof. A heat transfer fluid, such as brine or gas, flows through the flow path 120a. In one embodiment, the flow path 120a is formed in the base 120, and one or a plurality of heaters are disposed in the ceramic member 121a of the electrostatic chuck 121.

The shower head 13 is configured to introduce at least one processing gas from the gas supply 20 into the plasma processing space 10s. The shower head 13 includes at least one gas supply port 14, at least one gas diffusion chamber 15, and a plurality of gas introduction ports 16. The processing gas supplied to the gas supply port 14 passes through the gas diffusion chamber 15 and is introduced into the plasma processing space 10s from the plurality of gas introduction ports 16. The shower head 13 includes at least one upper electrode 17. The shower head 13 includes a cooling plate 18 provided above the upper electrode 17. The gas introduction unit may include, in addition to the shower head 13, one or a plurality of side gas injectors (SGI) that are attached to one or a plurality of openings formed in the sidewall 10a. Details of configurations of the gas introduction port 16, the upper electrode 17, and the cooling plate 18 will be described later.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes the RF power source 31 coupled to the plasma processing chamber 10 via at least one impedance matching circuit. The RF power source 31 includes RF power circuitry and is configured to supply at least one RF signal (RF power) to at least one lower electrode and/or at least one upper electrode. Plasma is thus generated from the at least one processing gas supplied into the plasma processing space 10s. Accordingly, the RF power source 31 may function as at least a part of the plasma generator 12. Supplying the bias RF signal to at least one lower electrode can generate a bias potential in the substrate W to attract an ionic component in the formed plasma to the substrate W.

In one embodiment, the RF power source 31 includes a first RF generator 31a (generator circuit) and a second RF generator 31b (generator circuit). The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate a bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 (DC power circuitry) coupled to the plasma processing chamber 10. The DC power source 32 includes a first DC generator 32a (generator circuit) and a second DC generator 32b (generator circuit). In one embodiment, the first DC generator 32a is connected to at least one lower electrode to generate a first DC signal. The generated first DC signal is applied to at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected, for example, to a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof. A baffle plate 140 is provided between the plasma processing space 10s and the gas exhaust port 10e. The baffle plate 140 includes a plurality of through-holes 141 that communicate with the plasma processing space 10s and the gas exhaust port 10e.

The configurations described above and illustrated in FIG. 2 include all plasma processing apparatus inner members according to the first to third embodiments to be described later. However, the configurations are not limited to these examples, and may include only any one of these components.

### First Embodiment

### Upper Electrode

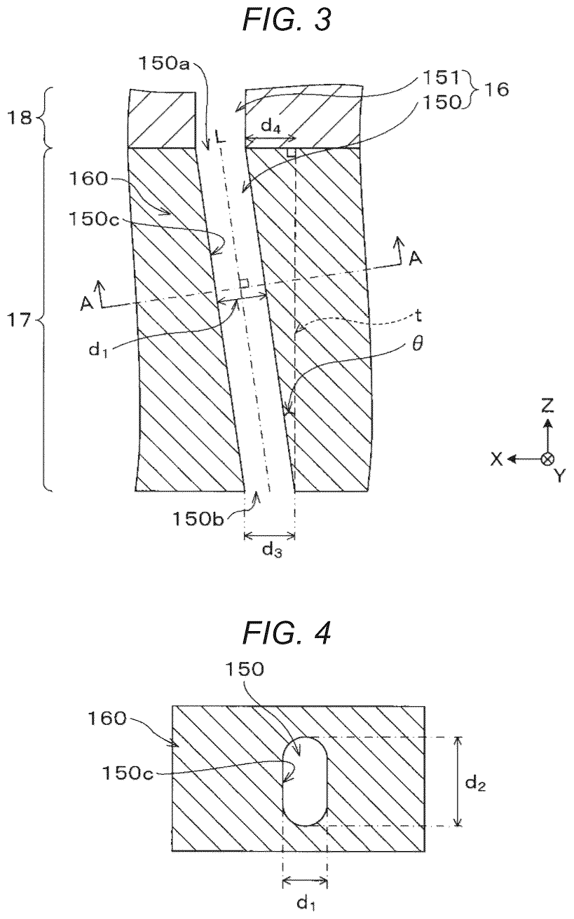

Hereinafter, configurations and modifications of the gas supply path in the upper electrode according to the first embodiment of the present disclosure will be described with reference to FIGS. 3 to 17. In each drawing, an X-axis is an axis showing a direction perpendicular to a thickness direction of the upper electrode 17, a Z-axis is an axis showing a direction parallel to the thickness direction of the upper electrode 17, and a Y-axis is an axis perpendicular to the X-axis and the Z-axis.

FIGS. 3 and 4 are partial cross-sectional views illustrating a configuration example of a first gas supply path 150 according to the first embodiment. FIG. 3 is a cross-section parallel to an inclination direction and a longitudinal direction L of the first gas supply path. FIG. 4 is a cross-section (cross-section taken along line A-A illustrated in FIG. 3) perpendicular to the longitudinal direction L of the gas supply path. In the example illustrated in FIG. 3, the inclination direction of the first gas supply path 150 is an X-axis positive direction.

In FIG. 3, the gas introduction port 16 includes the first gas supply path 150 formed in the upper electrode 17, and a second gas supply path 151 formed in the cooling plate 18. The first gas supply path 150 and the second gas supply path 151 communicate with each other at a connection surface between the upper electrode 17 and the cooling plate 18.

The first gas supply path 150 includes a first end 150a on a cooling plate 18 side and a second end 150b on a plasma processing space 10s side. At the first end 150a, the first gas supply path 150 is connected to the second gas supply path 151. The gas supplied to the gas introduction port 16 is introduced into the plasma processing space 10s via the second end 150b. A direction connecting centers of the first end 150a and the second end 150b will be referred to as the longitudinal direction L of the first gas supply path 150. The first gas supply path 150 is formed in a forming portion 160 in the upper electrode 17.

The forming portion 160 includes a wall surface 150c forming the first gas supply path 150. The forming portion 160 has a thickness t in a Z direction in FIG. 3. The thickness t of the forming portion 160 is 2 mm or more. The thickness t of the forming portion 160 is preferably 10 mm or more.

In FIG. 4, the first gas supply path 150 has a substantially rectangular shape with rounded corners in the cross-section (cross-section taken along line A-A illustrated in FIG. 3) perpendicular to the longitudinal direction L. In one embodiment, the rectangular shape with rounded corners is a shape in which a semicircle is connected to a pair of sides of a rectangle. The first gas supply path 150 has dimensions that include a representative length d₁ and a longest length d₂ in the cross-section perpendicular to the longitudinal direction L.

The representative length d₁ is a length of a part of the cross-section perpendicular to the longitudinal direction L that is closest to the wall surface 150c. The representative length d₁ is 0.5 mm or less. The representative length d₁ is preferably 0.1 mm or less. Meanwhile, a lower limit of a value of the representative length d₁ is not particularly limited, and may be 0.05 mm or more as the lower limit of the value formable in a method of forming the gas supply path to be described later.

The longest length d₂ is a length of a part where the wall surface 150c is the furthest away in the cross-section perpendicular to the longitudinal direction L. A lower limit of a value of the longest length d₂ is defined by a ratio (d₂/d₁) to the representative length d₁, and the ratio (d₂/d₁) is 2 or more. The ratio (d₂/d₁) is preferably 5 or more.

Referring back to FIG. 3, the first gas supply path 150 is inclined in a direction having a desired inclination angle θ with respect to the Z-axis. In other words, the inclination angle θ formed between the longitudinal direction L of the first gas supply path 150 and the Z-axis is not 0 (zero). θ is in radians, and 0<θ<(π/2) is satisfied.

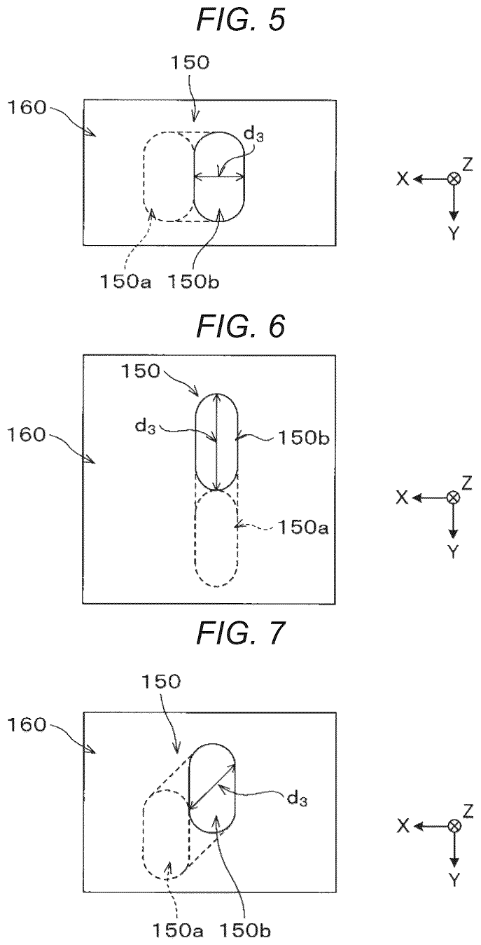

An inclination of the first gas supply path 150 and a significance thereof will be described with reference to FIGS. 3 to 7. FIG. 5 is a partial plan view of the gas supply path 150 according to the first embodiment viewed from the second end 150b in a Z-axis positive direction in FIG. 3. FIGS. 6 and 7 are partial plan views of modifications in which the inclination direction is different. A plan view viewed from the second end 150b in the Z-axis positive direction in FIG. 3 will be simply referred to as a “plan view” hereinafter.

In FIG. 5, the second end 150b has a dimension that includes a maximum length in the inclination direction d₃. The maximum length in the inclination direction d₃ is a length of a part where the wall surface 150c is furthest away in a linear distance in a direction parallel to the inclination direction. In other words, the maximum length in the inclination direction d₃ is the longest length among any line segment cut by the wall surface 150c and parallel to the inclination direction.

The example illustrated in FIG. 5 is when the inclination direction is the X-axis positive direction. At this time, the maximum length in the inclination direction d₃ is equal to a length of the first gas supply path 150 in a minor axis direction in the plan view.

In the example illustrated in FIG. 6, the inclination direction is a Y-axis positive direction. At this time, the maximum length in the inclination direction d₃ is equal to a length of the first gas supply path 150 in a major axis direction in the plan view.

In the example illustrated in FIG. 7, the inclination direction is an oblique direction with respect to each of the X-axis and the Y-axis.

Here, in the plan view of FIGS. 5 to 7, the first end 150a is not visible from the second end 150b. In one embodiment, in the plan view, only the wall surface 150c is visible from an opening that forms the second end 150b. This configuration is implemented in the present embodiment by the inclination of the first gas supply path 150.

More specifically, the configuration in which the first end 150a is not visible from the second end 150b in the plan view is achieved such that the thickness t of the forming portion 160, the inclination angle θ, and the maximum length in the inclination direction d₃ satisfy a relationship in formula (1) below.

$$tan θ \geq {d}_{3} / t \qquad ( 1 )$$

The significance of formula (1) above will be described with reference to FIG. 3. FIG. 3 is an example in which the inclination direction is the X-axis positive direction. However, the same applies to a case where the inclination direction is another direction (for example, the direction illustrated in FIGS. 6 and 7).

In the cross-sectional view in FIG. 3, the first gas supply path 150 is inclined so that the first end 150a is offset by a length d₄ in an X direction. The offset distance d₄ satisfies formula (2) below.

$${d}_{4} = t \times tan θ \qquad ( 2 )$$

When the offset distance d₄ is equal to or larger than the maximum length in the inclination direction d₃ (d₄>d₃), the first end 150a is not visible from the second end 150b. From this and formula (2), the above formula (1) is derived.

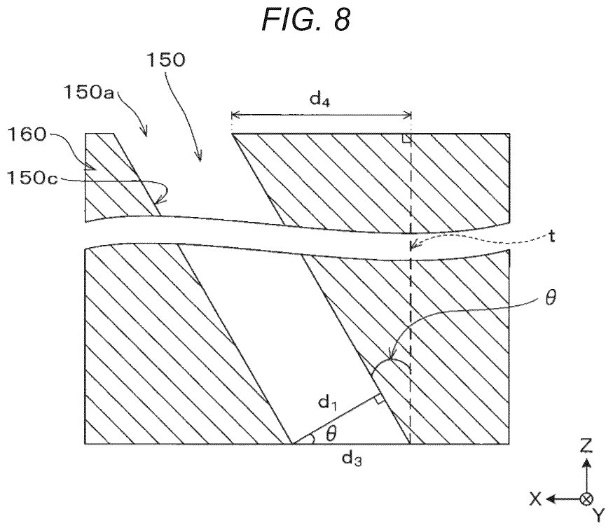

Here, when the inclination direction is the X-axis positive direction as illustrated in FIGS. 3 and 5, formula (3) below is established by a graphical relationship as illustrated in FIG. 8.

$${d}_{3} = {d}_{1} / cos θ \qquad ( 3 )$$

When the above formula (3) is substituted into formula (1) and transformed, formula (4) below is obtained.

$$sin θ \geq {d}_{1} / t \qquad ( 4 )$$

Similarly, when the inclination direction is the Y-axis positive direction as illustrated in FIG. 6, formula (5) below is established.

$$sin θ \geq {d}_{2} / t \qquad ( 5 )$$

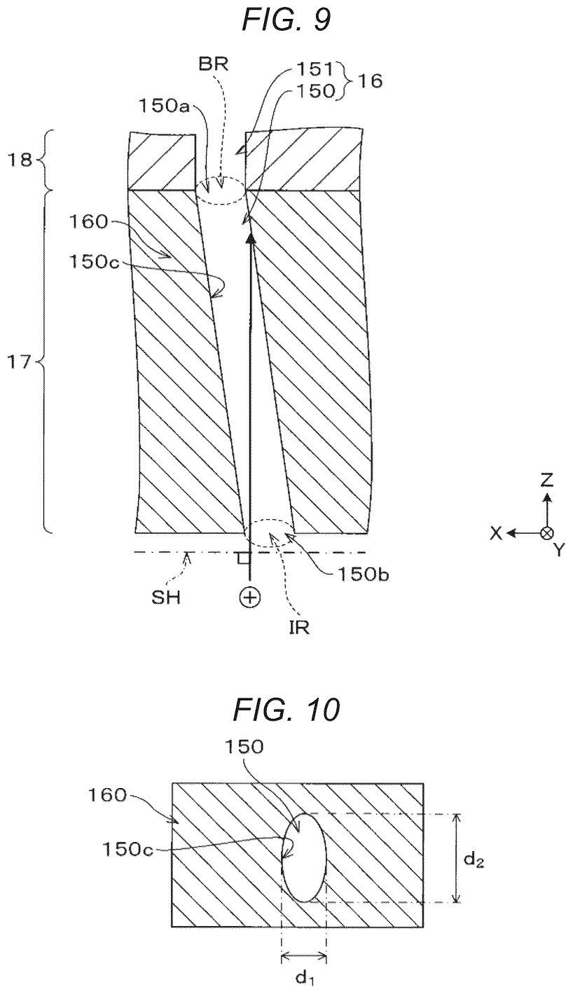

Next, an example of an operation of providing the first gas supply path 150 according to the first embodiment as described above will be described with reference to FIG. 9. FIG. 9 is a diagram illustrating an operation example of the gas supply path according to the first embodiment.

First, when the representative length d₁ is 0.5 mm or less, a proportion of positive ions (indicated by “+” in FIG. 9) entering the first gas supply path 150 from the plasma processing space 10s can be reduced. The positive ions entering the first gas supply path 150 are easily brought into contact with the wall surface 150c, and are unlikely to reach a boundary region BR between the upper electrode 17 and the cooling plate 18. Accordingly, it is possible to prevent occurrence of abnormal discharge caused by positive ions entering the boundary region BR.

When the ratio (d₂/d₁) of the longest length d₂ to the representative length d₁ is 2 or more, a gas molecule density in a gas introduction region IR around the second end 150b in the plasma processing space 10s can be reduced. By lowering the gas molecule density in the gas introduction region IR, ionization of the gas in the gas introduction region IR is reduced, and an amount of positive ions present is reduced. Accordingly, the number of positive ions entering the first gas supply path 150 can be reduced, and the occurrence of the abnormal discharge can be further reduced.

Further, since the first end 150a is configured so that the first end 150a is not visible from the second end 150b in the plan view, even when the positive ions accelerated in a direction perpendicular to a plasma sheath SH enter the first gas supply path 150, the positive ions do not reach the boundary region BR, but come into contact with the wall surface 150c. Accordingly, the occurrence of the abnormal discharge can be further reduced.

Secondary, the following effects can also be obtained. That is, when the ratio (d₂/d₁) of the longest length d₂ to the representative length d₁ is 2 or more, conductance of the first gas supply path 150 is increased compared with when the ratio is less than 2. Accordingly, it is possible to prevent the occurrence of the abnormal discharge without lowering a speed of gas introduction in the gas introduction unit.

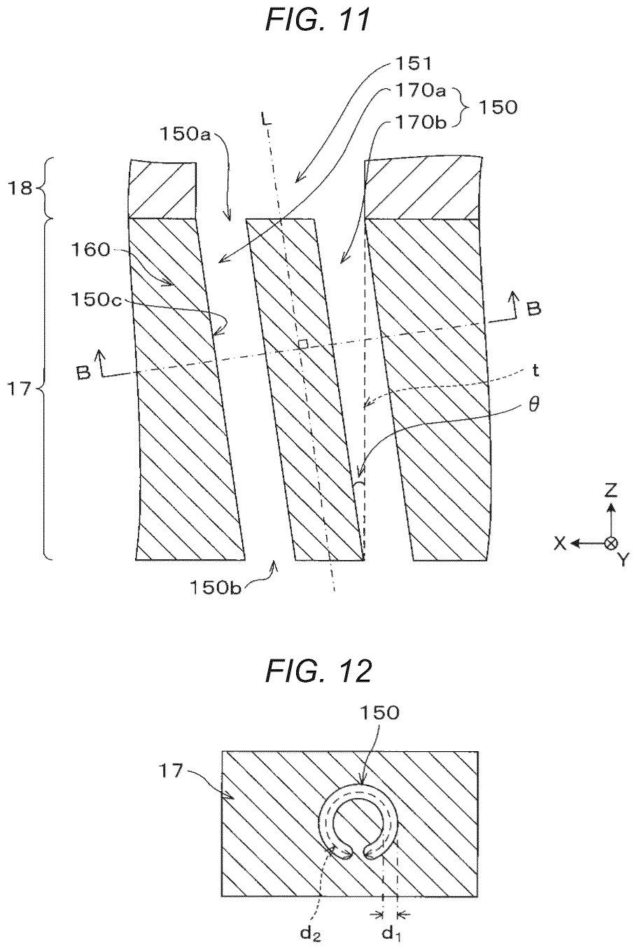

Hereinafter, a modification of the first gas supply path 150 according to the first embodiment will be described with reference to FIGS. 10 to 17.

FIG. 10 is a partial cross-sectional view illustrating the first gas supply path 150 according to one modification. In the modification illustrated in FIG. 10, the first gas supply path 150 has an elliptical shape in a cross-section perpendicular to the longitudinal direction L (cross-section taken along line A-A illustrated in FIG. 3). In this modification, the representative length d₁ is a length of a part closest to the wall surface 150c and is a minor axis of an ellipse. The longest length d₂ is a length of a part where the wall surface 150c is furthest away, and is a major axis of the ellipse. In this modification, each dimension can be specified by formula (4) or (5) above, as in the case where the cross-sectional shape is the rectangular shape with rounded corners.

FIG. 11 is a partial cross-sectional view illustrating a modification of the first gas supply path according to the first embodiment. In one modification, the first gas supply path 150 includes a plurality of sub-supply paths 170a and 170b in one cross-section parallel to the inclination direction and the longitudinal direction L, as illustrated in FIG. 11. The sub-supply paths 170a and 170b may communicate with each other in a circumferential direction of the first gas supply path 150, or may be independent without communicating with each other.

FIG. 12 is a partial cross-sectional view illustrating the first gas supply path 150 according to a modification. In the modification illustrated in FIG. 12, the first gas supply path 150 has a substantially C-shaped cross-section (cross-section taken along line B-B in FIG. 11) perpendicular to the longitudinal direction L. In this modification, the sub-supply paths 170a and 170b illustrated in FIG. 11 communicate with each other in the circumferential direction of the first gas supply path 150. In this modification, the representative length d₁ is a length of a part closest to the wall surface 150c, and is a length in a width direction of a C-shape as illustrated in FIG. 12. The longest length d₂ is a length of a part where the wall surface 150c is furthest away, and is a length in the circumferential direction of the C-shape as illustrated in FIG. 12.

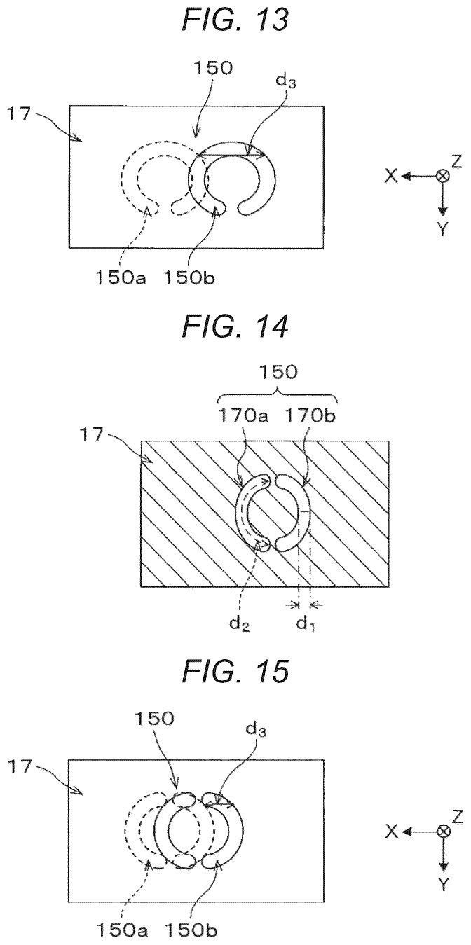

FIG. 13 is a partial plan view of the first gas supply path 150 according to the modification illustrated in FIGS. 11 and 12 viewed from the second end 150b in the Z-axis positive direction in FIG. 11. In FIG. 13, the second end 150b has a dimension that includes the maximum length in the inclination direction d₃. Accordingly, the first end 150a is not visible from the second end 150b in the plan view.

In FIG. 13, the second end 150b and the first end 150a overlap with each other in the plan view. However, when the maximum length in the inclination direction d₃ satisfies the formula (1), it is true that the other end is not visible from the one end even if the one end and the other end overlap with each other in the plan view. In FIG. 13, an overlapping portion is a shadow of the wall surface 150c, and thus the first end 150a is not visible from the second end 150b. The same applies to the other modifications to be described below according to the first embodiment.

FIG. 14 is a partial cross-sectional view illustrating the first gas supply path 150 according to another modification. In the modification illustrated in FIG. 14, in the first gas supply path 150, a set of shapes of cross-sections (cross-sections taken along line B-B illustrated in FIG. 11) perpendicular to the longitudinal direction L of the sub-supply paths 170a and 170b is a substantially C-shape facing each other. In this modification, the sub-supply paths 170a and 170b illustrated in FIG. 11 do not communicate with each other in the circumferential direction of the first gas supply path 150, and are independent of each other. In this modification, the representative length d₁ is a length of a part closest to the wall surface 150c, and is a length in a width direction of a C-shape as illustrated in FIG. 14. The longest length d₂ is a length of a part where the wall surface 150c is furthest away, and is a length in the circumferential direction of the C-shape as illustrated in FIG. 14.

FIG. 15 is a partial plan view of the first gas supply path 150 according to the modification illustrated in FIGS. 11 and 14 viewed from the second end 150b in the Z-axis positive direction in FIG. 11. In FIG. 13, the second end 150b has the dimension that includes the maximum length in the inclination direction d₃. Accordingly, the first end 150a is not visible from the second end 150b in the plan view.

FIG. 16 is a partial cross-sectional view illustrating the first gas supply path 150 according to still another modification. In the modification illustrated in FIG. 16, three sub-supply paths 170a, 170b, and 170c are provided, and the sub-supply paths 170a, 170b, and 170c do not communicate with each other in the circumferential direction of the first gas supply path 150 and are independent of each other. In each of the sub-supply paths 170a, 170b, and 170c, a shape of a cross-section (cross-section taken along line B-B illustrated in FIG. 11) perpendicular to the longitudinal direction L is a substantially involute curve shape, and a set of shapes of the cross-section is disposed at positions that are rotationally symmetrical by 120°. In this modification, the representative length d₁ is a length of a part closest to the wall surface 150c, and is a length in a width direction of a shape of the involute curve as illustrated in FIG. 16. The longest length d₂ is a length of a part where the wall surface 150c is furthest away, and is a length in the circumferential direction of the shape of the involute curve as illustrated in FIG. 16.

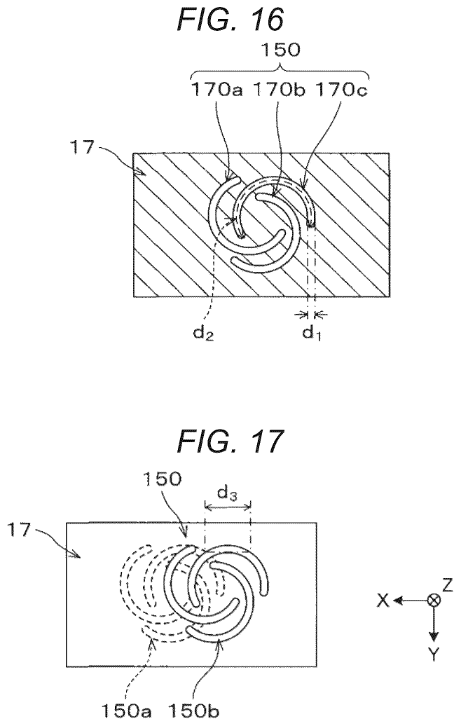

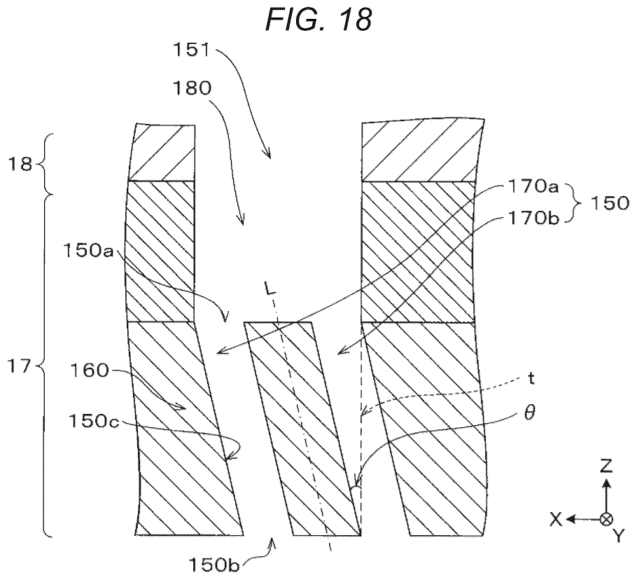

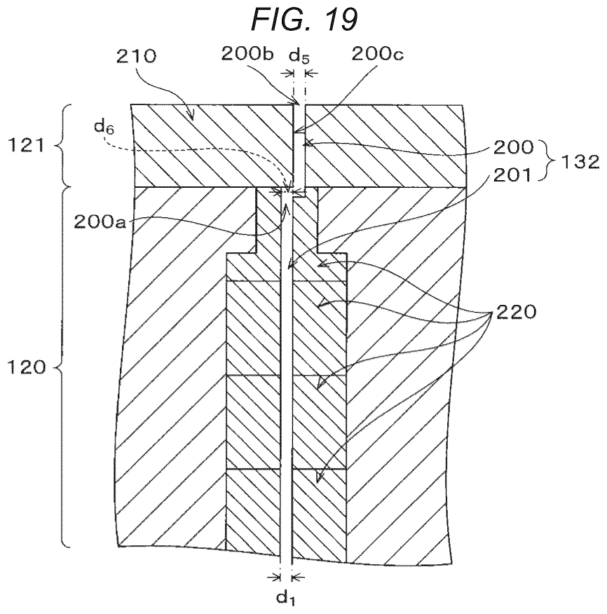

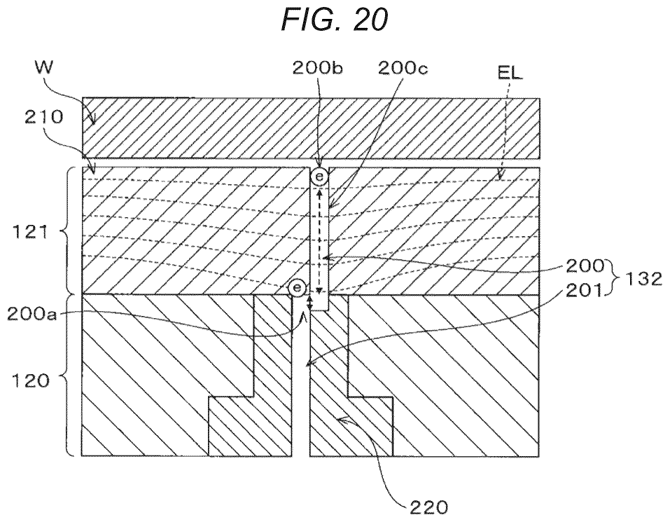

FIG. 17 is a partial plan view of the first gas supply path 150 according to the modification illustrated in FIGS. 11 and 16 viewed from the second end 150b in the Z-axis positive direction in FIG. 11. In FIG. 17, the second end 150b has the dimension that includes the maximum length in the inclination direction d₃. Accordingly, the first end 150a is not visible from the second end 150b in the plan view.

FIG. 18 is a partial cross-sectional view illustrating the first gas supply path 150 according to still another modification. In the modification illustrated in FIG. 18, the gas introduction port 16 further includes a third gas supply path 180 formed in the upper electrode 17. One end of the third gas supply path 180 and the second gas supply path 151 communicate with each other at the connection surface between the upper electrode 17 and the cooling plate 18. The other end of the third gas supply path 180 communicates with the first end 150a of the first gas supply path 150. That is, in this modification, the first gas supply path 150 and the second gas supply path 151 do not communicate with each other directly, but communicate with each other via the third gas supply path 180.

### Second Embodiment

### Electrostatic Chuck

Hereinafter, configurations and modifications of the gas supply path in the electrostatic chuck according to the second embodiment in the present disclosure will be described with reference to FIGS. 19 to 23.

FIG. 19 is a partial cross-sectional view illustrating a configuration example of a first gas supply path 200 according to the second embodiment. FIG. 19 is a cross-section of the first gas supply path taken along a plane parallel to the offset direction X and the longitudinal direction.

In FIG. 19, the heat transfer gas introduction port 132 includes the first gas supply path 200 formed in the electrostatic chuck 121 and a second gas supply path 201 formed in the base 120. The first gas supply path 200 and the second gas supply path 201 communicate with each other at a connection surface between the electrostatic chuck 121 and the base 120.

The first gas supply path 200 includes a first end 200a and a second end 200b on the rear surface (or the rear surface of the ring assembly) of the substrate W. At the first end 200a, the first gas supply path 200 is connected to the second gas supply path 201. The first gas supply path 200 is formed in a forming portion 210 of the electrostatic chuck 121. The forming portion 210 includes a wall surface 200c forming the first gas supply path 200. The second end 200b of the first gas supply path 200 may be provided in a sleeve 220 (described later) provided in the base 120 as illustrated in the drawing, or may be provided in the electrostatic chuck 121. The heat transfer gas supplied to the heat transfer gas introduction port 132 is supplied to a gap between the rear surface of the substrate W and the central region 111a or a gap between the rear surface of the ring assembly 112 and the annular region 111b via the first end 200a.

The second gas supply path 201 is formed in a plurality of sleeves 220 embedded in the base 120. In other words, ends of the divided second gas supply paths 201 formed in the sleeves 220 are connected to each other, thereby forming one second gas supply path 201 in communication as illustrated in the drawing. The sleeve 220 may be integrally formed without being divided.

In one embodiment, the first gas supply path 200 and the second gas supply path 201 have, in a cross-section perpendicular to the longitudinal direction, a rectangular shape with rounded corners similar to that illustrated in FIG. 4, and have dimensions that include the representative length d₁ and the longest length d₂. In this case, specific values of the representative length d₁ and the ratio (d₂/d₁) of the longest length d₂ to the representative length d₁ are similar as in the first embodiment.

In the first gas supply path 200, the first end 200a is not visible from the second end 200b in the plan view. In one embodiment, only the sleeve 220 is visible from the second end 200b in the plan view. This configuration is achieved in the present embodiment by the first gas supply path 200 being offset from the second gas supply path 201. When a maximum length in the offset direction in the plan view is d₅ and an offset distance is d₆, a configuration in which the first end 200a is not visible from the second end 200b is achieved as long as the offset distance do is equal to or larger than the maximum length in the offset direction d₅ (d₆≥d₅) in accordance with a similar spirit as described in the first embodiment.

Next, an example of an operation of providing the first gas supply path 200 according to the second embodiment as described above will be described with reference to FIG. 20. FIG. 20 is a diagram illustrating an operation example of the first gas supply path 200 according to the second embodiment.

First, when the representative length d₁ is 0.5 mm or less, electrons (indicated by “e” in FIG. 20) generated by ionization of the heat transfer gas in the first gas supply path 200 easily come into contact with the wall surface 200c, so that it is possible to shorten a straight travelling distance of the electrons. Accordingly, it is possible to prevent occurrence of abnormal discharge caused by a potential difference in the first gas supply path 200 or the second gas supply path 201.

When the ratio (d₂/d₁) of the longest length d₂ to the representative length d₁ is 2 or more, heat transfer gas molecule densities in the first gas supply path 200 and the second gas supply path 201 can be reduced. By lowering the heat transfer gas molecule density, the ionization of the heat transfer gas is reduced, and the occurrence of the abnormal discharge caused by the potential difference can be further reduced.

Further, with the configuration in which the first end 200a is not visible from the second end 200b in the plan view, electrons accelerated in a direction perpendicular to an equipotential line EL indicating the potential difference come into contact with the sleeve 220 even when the electrons move to a maximum extent. Accordingly, the occurrence of the abnormal discharge can be further reduced.

Secondary, the following effects can also be obtained. That is, when the ratio (d₂/d₁) of the longest length d₂ to the representative length d₁ is 2 or more, conductance of the first gas supply path 200 and the second gas supply path 201 is increased compared with when the ratio is less than 2. Accordingly, it is possible to prevent the occurrence of the abnormal discharge without lowering a speed of heat transfer gas introduction in the heat transfer gas introduction port 132.

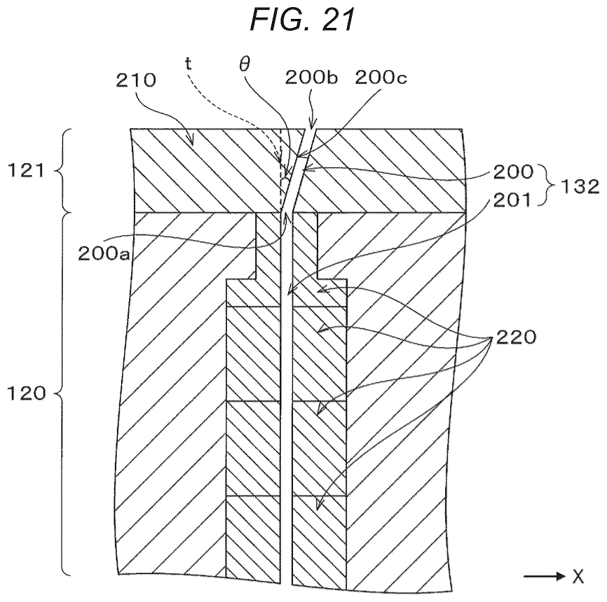

Hereinafter, modifications of the first gas supply path 200 and the second gas supply path 201 according to the second embodiment will be described with reference to FIGS. 21 to 23.

FIG. 21 is a partial cross-sectional view illustrating the first gas supply path 200 and the second gas supply path 201 according to the modification. In this modification, the first gas supply path 200 is inclined by the inclination angle θ in an inclination direction (the X-axis positive direction), as illustrated in FIG. 21. The inclination angle θ, the thickness t of the forming portion 210, and the maximum length in the inclination direction d₃ in this case are defined in the same manner as in the first embodiment, and when formula (1) above is satisfied, the first end 200a is not visible from the second end 200b.

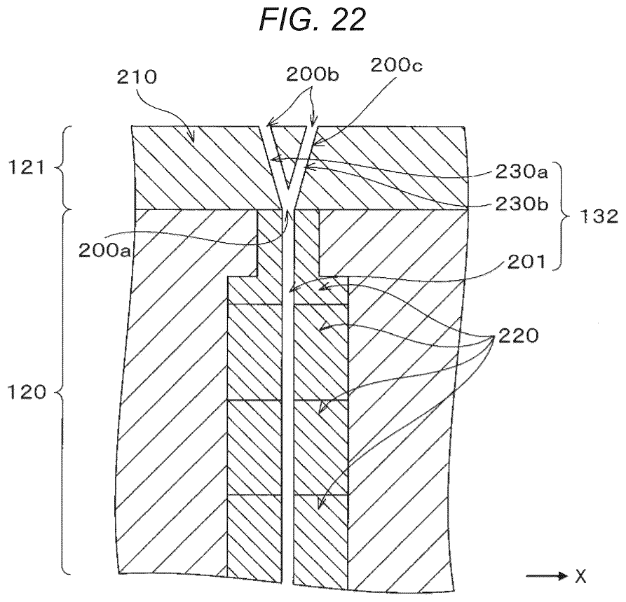

FIG. 22 is a partial cross-sectional view illustrating the first gas supply path 200 and the second gas supply path 201 according to another modification. In this modification, the first gas supply path 200 includes a plurality of sub-supply paths 230a and 230b as illustrated in FIG. 22. The one sub-supply path 230b is inclined in the X-axis positive direction, and the other sub-supply path 230a is inclined in an X-axis negative direction. Each of the sub-supply paths 230a and 230b has similar dimensions as those in the modification illustrated in FIG. 21, merges with the first end 200a, and is connected to the second gas supply path 201. In this modification as well, the first end 200a is not visible from the second end 200b.

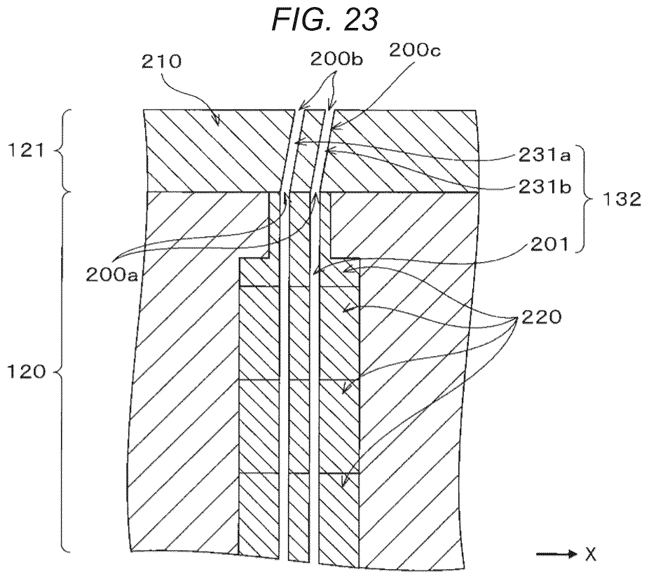

FIG. 23 is a partial cross-sectional view illustrating the first gas supply path 200 and the second gas supply path 201 according to still another modification. In this modification, the first gas supply path 200 includes a plurality of sub-supply paths 231a and 231b as illustrated in FIG. 23. The sub-supply paths 231a and 231b do not communicate with each other in a circumferential direction of the first gas supply path 200 and the second gas supply path 201, and are independent of each other. Each of the sub-supply paths 231a and 231b has similar dimensions and inclination as those in the modification illustrated in FIG. 21, merges with the first end 200a, and is connected to the second gas supply path 201. In this modification as well, the first end 200a is not visible from the second end 200b. In FIG. 23, a shape of the first gas supply path 200 and the second gas supply path 201 in the cross-section perpendicular to the longitudinal direction may be any of the shapes illustrated in FIGS. 12 to 17 according to a modification of the first embodiment. The same applies to an inclination mode.

### Third Embodiment

### Baffle Plate

The through-hole 141 provided in the baffle plate 140 may have a similar configuration as the first gas supply paths 150 and 200 and the like. Accordingly, it is possible to prevent occurrence of abnormal discharge in the through-hole 141, the gas exhaust port 10e, or the like.

### Method of Forming Gas Supply Path or Through-hole

The first gas supply path 150 and the second gas supply path 151 according to the first embodiment, the first gas supply path 200 and the second gas supply path 201 according to the second embodiment, and the through-hole 141 according to the third embodiment described above can be formed by, for example, water laser processing (also referred to as water jet laser processing or water beam laser processing).

In the water laser processing, a jet stream of water or liquid is ejected toward the forming portion (the forming portions 160, 210, the sleeve 220, or a base of the baffle plate) of the gas supply path in the upper electrode 17, the electrostatic chuck 121, the baffle plate 140, or the like, and a laser beam is made to advance while being confined in the jet stream by the principle of an optical fiber. At an end of the jet stream, processing is performed by the laser beam, and the forming portion is cooled by the jet stream, and processing waste is exhausted. Compared with the processing method in the related art described above, a hole having a high aspect ratio can be formed, and the representative length d₁ of the first gas supply path 150 (including the sub-supply paths 170a and 170b) according to the first embodiment, the representative lengths d₁ of the first gas supply path 200 and the second gas supply path 201 according to the second embodiment, and a width of the through-hole 141 according to the third embodiment can be 0.5 mm or less. Compared with the laser processing in the related art, there is the advantage that a laser focus is maintained using a water jet, so that adjustment of a focal depth is not necessary. As an example, the water laser processing can be performed using a laser processing machine “Luminizer LB300/LB500” manufactured by Makino Milling Machine Co., Ltd. (“Makino Milling Machine Co., Ltd.” and “Luminizer” are registered trademarks).

One plasma processing apparatus inner member may be implemented by combining a plurality of members in which holes are formed by the water laser processing. In this case, in the modification illustrated in FIG. 18 in the first embodiment, the first gas supply path 150 may be formed by water laser processing, the third gas supply path 180 may be formed by MC processing, and the one upper electrode 17 may be implemented by combining these. In the second embodiment, the base 120 having the second gas supply path 201 may be implemented by forming a hole for each of the plurality of sleeves 220 by water laser processing, forming a through-hole in the base 120 by MC processing, and embedding the plurality of sleeves 220 in the through-hole.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art from the description herein can be obtained.

The effects described herein are merely illustrative or exemplary, and are not limited. In other words, the technique according to the present disclosure may have other effects apparent to those skilled in the art from the description herein, in addition to or in place of the effects described above.

1. A plasma processing apparatus, comprising:
a plasma processing apparatus inner member including
a gas supply path and a forming portion in which the gas supply path is formed,
the gas supply path has a representative length d₁ and a longest length d₂ in a cross-section perpendicular to a longitudinal direction of the gas supply path,
the representative length d₁ is 0.5 mm or less,
a ratio d₂/d₁ of the longest length d₂ to the representative length d₁ is 2 or more,
an other end is not visible from one end in a plan view, and
the forming portion has a thickness of 2 mm or more.

2. The plasma processing apparatus according to claim 1, wherein
when t is a thickness of the forming portion, θ is an inclination angle of the gas supply path with respect to a thickness direction of the forming portion, and d₃ is a maximum length in an inclination direction of the gas supply path in the plan view, values of t, d₃ and θ are such that formula (1) below is satisfied.
$$tan θ \geq {d}_{3} / t . \qquad ( 1 )$$

3. The plasma processing apparatus according to claim 2, wherein
a cross-sectional shape of the gas supply path in the cross-section is a rectangular shape with rounded corners.

4. The plasma processing apparatus according to claim 3, wherein
the gas supply path
satisfies formula (2) below when the inclination direction is a minor axis direction of the gas supply path in the plan view, and
satisfies formula (3) below when the inclination direction is a major axis direction of the gas supply path in the plan view.
$$sin θ \geq {d}_{1} / t \qquad ( 2 )$$
$$sin θ \geq {d}_{2} / t . \qquad ( 3 )$$

5. The plasma processing apparatus according to claim 2, wherein
a cross-sectional shape of the gas supply path in the cross-section is elliptical.

6. The plasma processing apparatus according to claim 5, wherein
the gas supply path
satisfies formula (2) below when the inclination direction is a minor axis direction of the gas supply path in the plan view, and
satisfies formula (3) below when the inclination direction is a major axis direction of the gas supply path in the plan view.
$$sin θ \geq {d}_{1} / t \qquad ( 2 )$$
$$sin θ \geq {d}_{2} / t . \qquad ( 3 )$$

7. The plasma processing apparatus according to claim 2, wherein
a cross-sectional shape of the gas supply path in the cross-section is a C-shape.

8. The plasma processing apparatus according to claim 2, wherein
the gas supply path includes a plurality of sub-supply paths, and a set of cross-sectional shapes of one of the plurality of sub-supply paths and another of the plurality of sub-supply paths in the cross-section is a C-shape facing each other.

9. The plasma processing apparatus according to claim 2, wherein
the gas supply path includes a plurality of sub-supply paths, a cross-sectional shape of each of the plurality of sub-supply paths in the cross-section is an involute curve shape, and a set of the cross-sectional shapes of the plurality of sub-supply paths is provided in a rotationally symmetrical manner.

10. The plasma processing apparatus according to claim 1, wherein
the plasma processing apparatus inner member constitutes a shower head.

11. The plasma processing apparatus according to claim 10, wherein
the forming portion is provided in an upper electrode.

12. The plasma processing apparatus according to claim 1, wherein
the plasma processing apparatus inner member includes a heat transfer gas supply.

13. The plasma processing apparatus according to claim 12, wherein
the forming portion is provided in an electrostatic chuck.

14. The plasma processing apparatus according to claim 1, wherein
the plasma processing apparatus inner member includes a baffle plate.

15. A plasma processing apparatus inner member comprising:
a gas supply path, and
a forming portion in which the gas supply path is formed, wherein
the gas supply path has a representative length d₁ and a longest length d₂ in a cross-section perpendicular to a longitudinal direction of the gas supply path,
the representative length d₁ is 0.5 mm or less,
a ratio d₂/d₁ of the longest length d₂ to the representative length d₁ is 2 or more,
an other end is not visible from one end in a plan view, and
the forming portion has a thickness of 2 mm or more.

16. The plasma processing apparatus inner member according to claim 15, wherein
when t is a thickness of the forming portion, θ is an inclination angle of the gas supply path with respect to a thickness direction of the forming portion, and d₃ is a maximum length in an inclination direction of the gas supply path in the plan view, values of t, d₃ and θ are such that formula (1) below is satisfied.
$$tan θ \geq {d}_{3} / t . \qquad ( 1 )$$

17. The plasma processing apparatus inner member according to claim 16, wherein
a cross-sectional shape of the gas supply path in the cross-section is a rectangular shape with rounded corners.

18. The plasma processing apparatus inner member according to claim 17, wherein
the gas supply path
satisfies formula (2) below when the inclination direction is a minor axis direction of the gas supply path in the plan view, and
satisfies formula (3) below when the inclination direction is a major axis direction of the gas supply path in the plan view.
$$sin θ \geq {d}_{1} / t \qquad ( 2 )$$
$$sin θ \geq {d}_{2} / t . \qquad ( 3 )$$

19. The plasma processing apparatus inner member according to claim 16, wherein
a cross-sectional shape of the gas supply path in the cross-section is elliptical.

20. The plasma processing apparatus inner member according to claim 19, wherein
the gas supply path
satisfies formula (2) below when the inclination direction is a minor axis direction of the gas supply path in the plan view, and
satisfies formula (3) below when the inclination direction is a major axis direction of the gas supply path in the plan view.
$$sin θ \geq {d}_{1} / t \qquad ( 2 )$$
$$sin θ \geq {d}_{2} / t . \qquad ( 3 )$$
